(19) United States
(12) Patent Application Publication
(10) Pub. No.: US 2019/0347909 A1
(43) Pub. Date: Nov. 14, 2019

(54) PROCESSING TERMINAL

(71) Applicant: TOSHIBA TEC KABUSHIKI KAISHA, Tokyo (JP)

(72) Inventor: Toshihiro Kaneko, Izunokuni Shizuoka (JP)

(21) Appl. No.: 16/411,185

(22) Filed: May 14, 2019

(30) Foreign Application Priority Data
May 14, 2018 (JP) 2018-093192

(51) Int. Cl. G07G 1/00; B41J 3/44; H05K 5/02; H05K 5/00

(52) U.S. Cl. CPC G07G 1/0018; B41J 3/445; G07G 1/0045; H05K 5/0217; H05K 5/0017; H05K 5/0221

(57) ABSTRACT

A processing terminal includes a first housing, a second housing, a rotating shaft, a damper, and an urging member. The rotating shaft rotatably supports the second housing with respect to the first housing. The damper is provided in the rotating shaft and brakes rotation of the second housing between an open position where the second housing is separated from the first housing and a closed position where the second housing covers the first housing. The urging member is provided in the rotating shaft and urges the second housing from the closed position toward the open position at least in the closed position.

### CROSS-REFERENCE TO RELATED APPLICATION

This application is based upon and claims the benefit of priority from Japanese Patent Application No. 2018-093192, filed in May 14, 2018, the entire contents of which are incorporated herein by reference.

### FIELD

Embodiments described herein relate generally to a processing terminal.

### BACKGROUND

As an apparatus that performs settlement processing in a store or the like, there has been known a processing terminal in which a second housing that covers a first housing rotates in a predetermined angle range with respect to the first housing. Such a processing terminal includes, on the inside, a storing section that stores roll paper to be printed by a printer. Therefore, during supply of the roll paper, operation for rotating the second housing with respect to the first housing to open and close the processing terminal is necessary.

However, if a display, a substrate, and the like are disposed in the second housing, the weight of the second housing increases. A large force is necessary to operate the second housing in the opening and closing operation of the processing terminal. Therefore, operability of the processing terminal is likely to be deteriorated.

Related art is described in, for example, JP-A-2015-146350.

### DESCRIPTION OF THE DRAWINGS

FIG. 1 is a perspective view illustrating the configuration of a processing terminal according to an embodiment and an example of a closed state in which a second housing covers a first housing;

FIG. 2 is a perspective view illustrating the configuration of the processing terminal and an example of an open state in which the second housing is erected with respect to the first housing;

FIG. 3 is a block diagram illustrating the configuration of the processing terminal;

FIG. 4 is a perspective view illustrating the configuration of a rear surface of the processing terminal;

FIG. 5 is a perspective view illustrating the configuration of a bottom surface of the processing terminal;

FIG. 6 is a sectional view illustrating the configuration of the processing terminal;

FIG. 7 is a perspective view illustrating the configuration of the first housing of the processing terminal;

FIG. 8 is a perspective view illustrating the configuration of the second housing of the processing terminal;

FIG. 9 is a perspective view illustrating the configuration of a hinge section of the processing terminal;

FIG. 10 is a side view illustrating the configuration of the hinge section;

FIG. 11 is a perspective view illustrating the configuration of a cable of the processing terminal;

FIG. 12 is a perspective view illustrating the configuration of a hinge section of a processing terminal according to another embodiment; and

FIG. 13 is a side view illustrating the configuration of the hinge section.

### DETAILED DESCRIPTION

An object of embodiments is to provide a processing terminal that can improve operability.

A processing terminal according to an embodiment includes a first housing, a second housing, a rotating shaft, a damper, and an urging member. The rotating shaft rotatably supports the second housing with respect to the first housing. The damper is provided in the rotating shaft and brakes rotation of the second housing between an open position where the second housing is separated from the first housing and a closed position where the second housing covers the first housing. The urging member is provided in the rotating shaft and urges the second housing from the closed position toward the open position at least in the closed position.

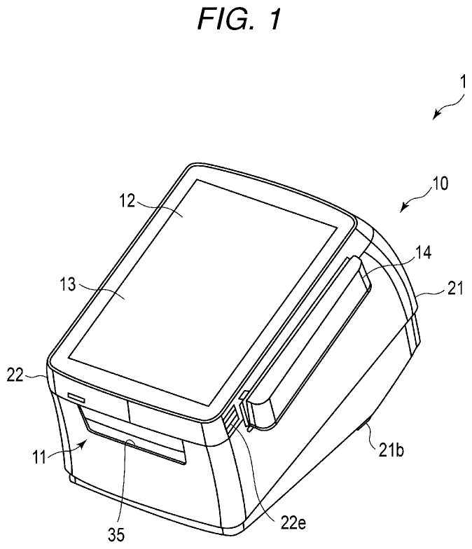

A processing terminal 1 according to an embodiment is explained with reference to FIGS. 1 to 11.

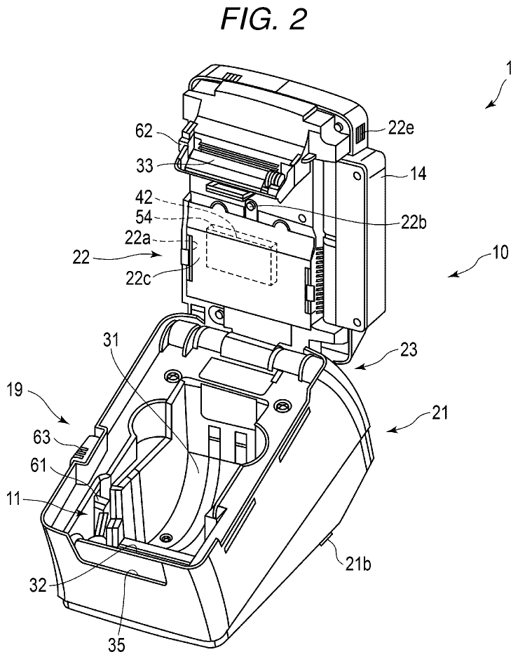

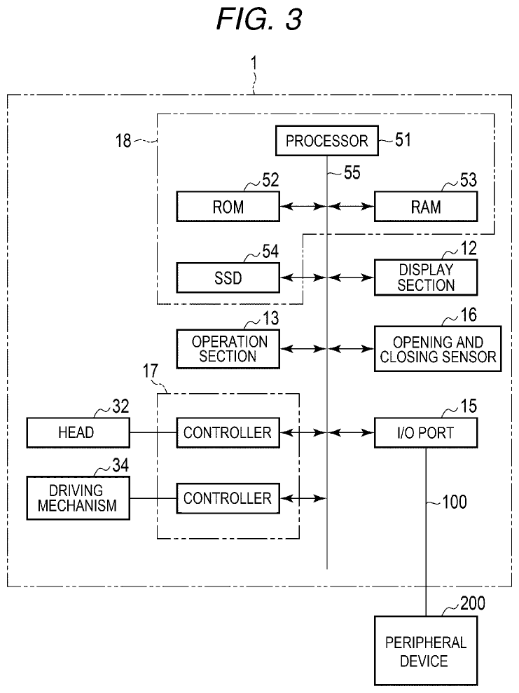

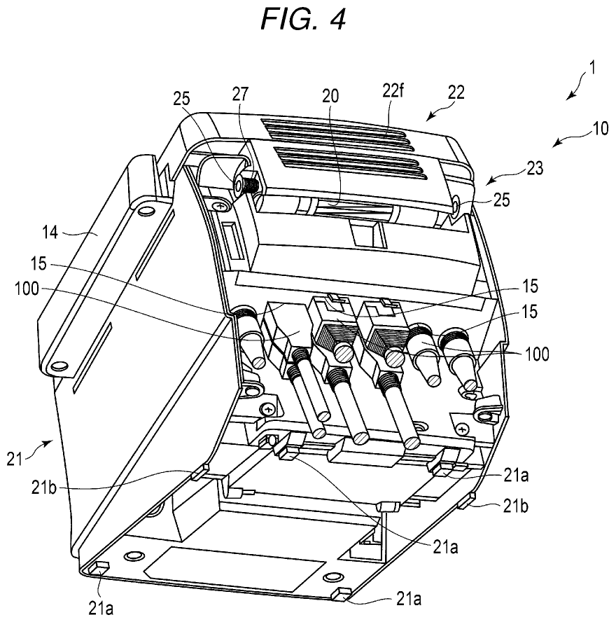

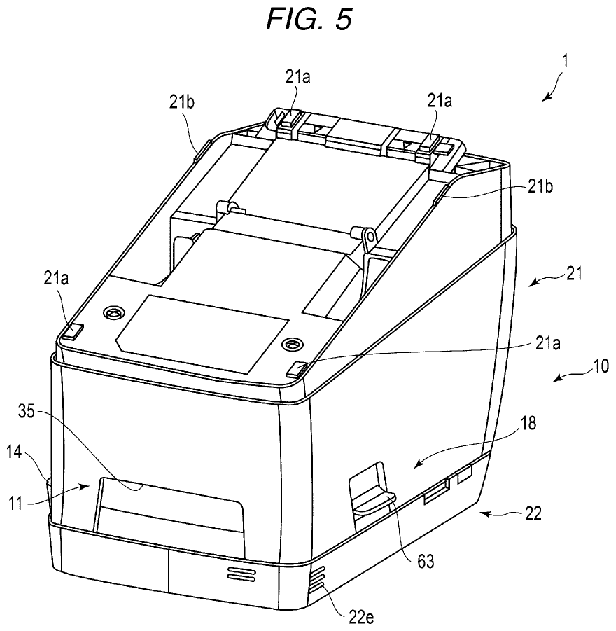

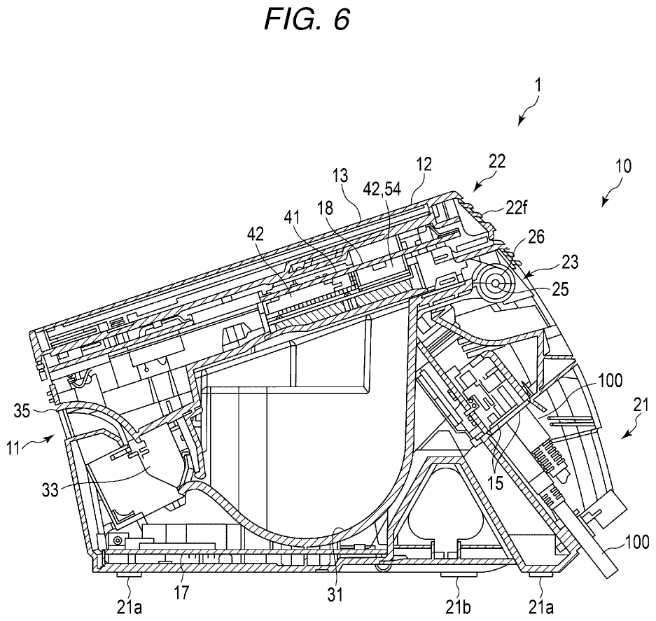

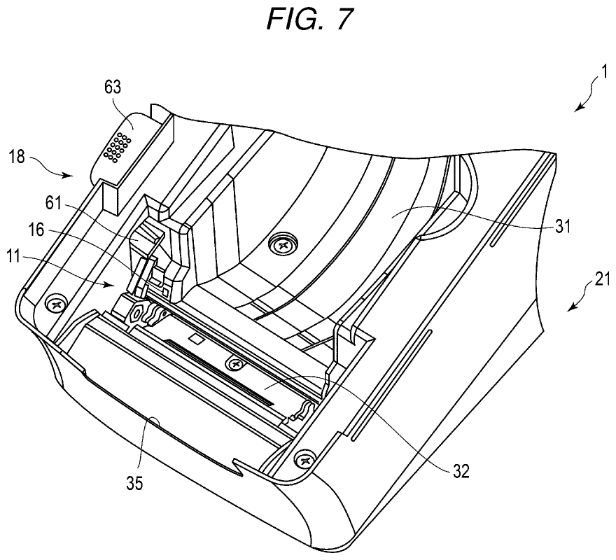

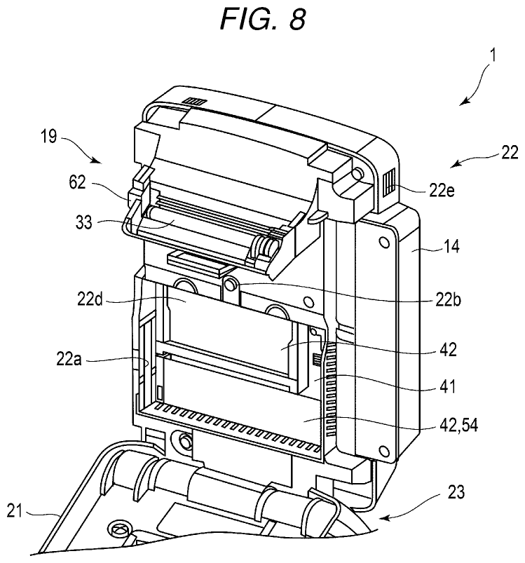

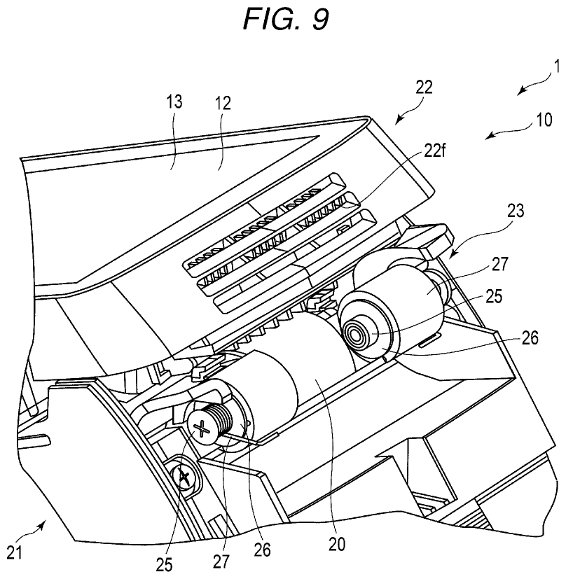

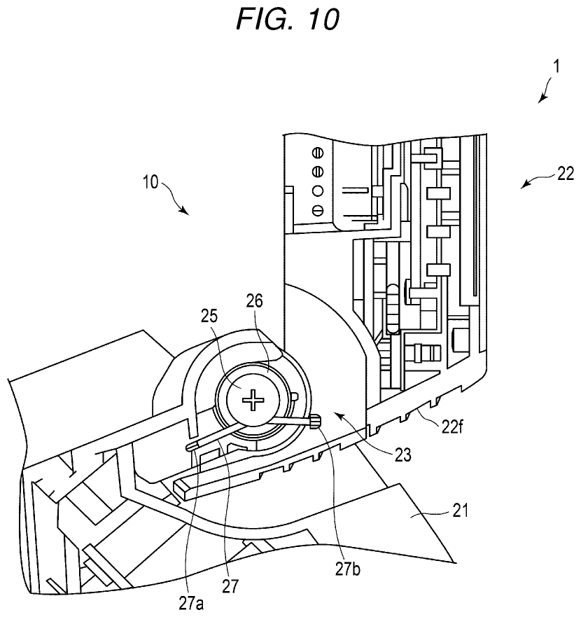

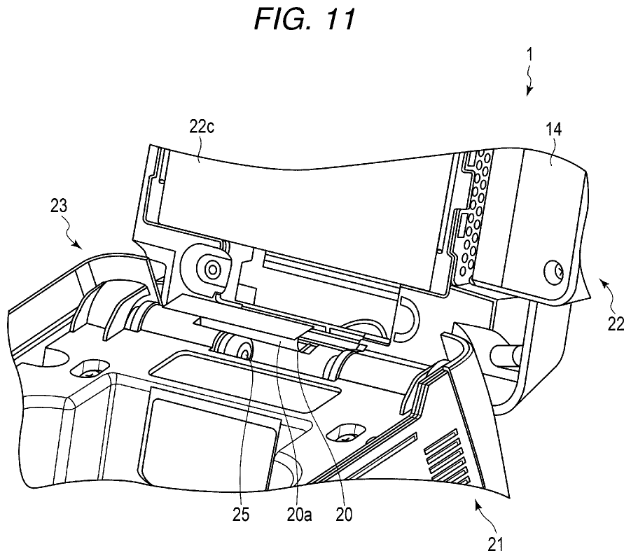

FIGS. 1 and 2 are perspective views illustrating the configuration of a processing terminal 1 according to this embodiment. FIG. 1 illustrates a state in which a second housing 22 covers a first housing 21. FIG. 2 illustrates a state in which the second housing 22 is erected with respect to the first housing 21. FIG. 3 is a block diagram illustrating the configuration of the processing terminal 1. FIGS. 4 and 5 are perspective views respectively illustrating the configuration of the processing terminal 1 from a rear surface side and a bottom surface side. FIG. 6 is a sectional view illustrating the configuration of the processing terminal 1. FIG. 7 is a perspective view illustrating the configuration of the first housing 21 from an upper surface side. FIG. 8 is a perspective view illustrating the configuration of the second housing 22. FIGS. 9 and 10 are a perspective view and a side view respectively illustrating the configuration of a hinge section 23 of the processing terminal 1. FIG. 11 is a perspective view illustrating the configuration of the processing terminal 1 and a relation between the hinge section 23 and a cable 20.

In the following explanation in this embodiment, an up-down direction is defined with the first housing 21 side set as a lower side and the second housing 22 side set as an upper side in a posture in which the processing terminal 1 is set on a setting surface. A front-rear direction is defined with the hinge section 23 side set as a rear surface side and a side opposed to the hinge section 23 side set as a front surface side.

As illustrated in FIGS. 1 and 6, the processing terminal 1 includes a housing 10, a printer 11, a display section 12, an operation section 13, a card reader writer 14, an I/O (Input/Output) port 15, an opening and closing sensor 16, a first substrate 17, a second substrate 18, a lock mechanism 19, and a cable 20. The processing terminal 1 is, for example, a POS (point of sale) terminal set in a store and used to perform settlement processing such as input and communication of sales information, receipt issuance, and reading and the like of information of a credit card and the like.

As illustrated in FIGS. 1 and 2, the housing 10 includes the first housing 21 set on the setting surface, the second housing 22 configured to rotate with respect to the first housing 21, and the hinge section 23 configured to rotatably couple the first housing 21 and the second housing 22. The housing 10 is configured in a substantially rectangular box shape, an upper surface of which inclines downward from the hinge section 23 side toward the side opposed to the hinge section 23 in a state in which the second housing 22 covers the first housing 21.

As illustrated in FIGS. 1 to 4, the first housing 21 is configured in a rectangular box shape, an upper surface of which inclines from the rear surface side toward the front surface side and is opened. The first housing 21 houses or holds a part of components of the printer 11, the I/O port 15, the opening and closing sensor 16, the first substrate 17, and the like. As illustrated in FIG. 2, the first housing 21 includes, on the upper surface, a sheet storing section 31, which is a hollow that stores roll paper used in the printer 11. Such a first housing 21 is configured by, for example, fixing a plurality of decorative panels configuring an outer wall to a frame. For example, a part of the decorative panels is detachably fixed to the frame.

The first housing 21 includes, as illustrated in FIGS. 4 to 6, for example, on the lower surface, a plurality of legs 21a and a plurality of auxiliary legs 21b. In this embodiment, the first housing 21 includes four legs 21a and two auxiliary legs 21b.

The legs 21a are formed of a resin material having a large coefficient of friction, for example, rubber. The legs 21a come into contact with the setting surface to suppress the first housing 21 from moving along the setting surface if an external force is applied to the first housing 21. Two legs 21a are disposed on the front surface side of the lower surface of the first housing 21. Two legs 21a are disposed on the rear surface side of the lower surface of the first housing 21.

The auxiliary legs 21b are protrusions provided integrally with the first housing 21. The auxiliary legs 21b are disposed on the lower surface of the first housing 21 and respectively disposed between the legs 21a on the front surface side and the legs 21a on the rear surface side of the first housing 21.

As illustrated in FIGS. 1 to 3 and FIG. 6, the second housing 22 houses or holds a part of the components of the printer 11, the display section 12, the operation section 13, the card reader writer 14, the second substrate 18, and the like. The second housing 22 is configured in a rectangular plate shape and includes, on the inside, a space for housing the second substrate 18. The second housing 22 is a cover that covers the upper surface of the first housing 21.

The second housing 22 rotates with the hinge section 23 as a rotation center in a predetermined angle range with respect to the first housing 21. Specifically, the second housing 22 is operated by a user to perform a circular motion around the rotation center of the hinge section 23 between a closed position and an open position.

The closed position is a position where a part of a surface of the second housing 22 opposed to the first housing 21 is in contact with the upper surface of the first housing 21. The closed position is a position where an extending direction of the second housing 22 is orthogonal to the setting surface of the first housing 21 or a position slightly rotated in a direction further away from the first housing 21 than the orthogonal position.

That is, the second housing 22 is configured in a shape in contact with the upper surface of the first housing 21 in the closed position and in contact with a part of the rear surface of the first housing 21 in the closed position. The second housing 22 can reciprocate around the center axis of the hinge section 23 with respect to the first housing 21 between the closed position and the open position. The second housing 22 is restricted from moving beyond the closed position and the open position.

The closed position of the second housing 22 can be set as appropriate if the closed position is a position where the sheet storing section 31 provided on the upper surface of the first housing 21 is exposed and the roll paper can be supplied and the second housing 22 does not move with the own weight thereof.

As a specific example, the display section 12 and the operation section 13 are disposed on the upper surface of the second housing 22, whereby the second housing 22 configures a display unit that the user can operate. As illustrated in FIG. 2, the second housing 22 includes, on the surface opposed to the first housing 21, an opening 22a and a cover 22c detachably attachable to the opening 22a by a screw 22b. As illustrated in FIG. 8, a mounting section 22d is provided on the inside of the second housing 22.

As illustrated in FIGS. 1, 2, and 4, the second housing 22 includes intake ports 22e provided at end portions on the front surface side of both side surfaces and exhaust ports 22f provided on the rear surface side. On the inside of the second housing 22, a wall, a rib, a pipe, and the like configuring parts of a channel of the air from the intake ports 22e to the exhaust ports 22f are provided as appropriate according to the second substrate 18 and other components housed on the inside of the second housing 22.

As illustrated in FIGS. 2 and 8, an opening area of the opening 22a is set to size for enabling a replaceable replacement member 54 provided on the second substrate 18 to move. The opening 22a is disposed on the hinge section 23 side of the outer surface section on the first housing 21 side of the second housing 22. The outer surface section on the first housing 21 side of the second housing 22 is a part of the second housing 22 opposed to the first housing 21 if the second housing 22 is present in the closed position. A screw hole, in which the screw 22b is screwed, is provided around the opening 22a of the second housing 22.

As illustrated in FIGS. 2 and 8, the cover 22c covers the opening 22a. The cover 22c may include a hole for ventilation. The cover 22c is attached to the opening 22a by, for example, screwing the screw 22b in the screw hole.

As illustrated in FIG. 8, the mounting section 22d is disposed in a position opposed to the opening 22a on the inside of the second housing 22. Specifically, the mounting section 22d is configured by a part of the second substrate 18 opposed to the opening 22a, to and from which the replacement member 54 can be attached and detached. As a specific example, the mounting section 22d is configured by an attachment to which the replacement member 54 provided on the second substrate 18 is connected and a screw hole in which a screw inserted through the replacement member 54 is screwed.

As illustrated in FIGS. 1 and 2, the intake ports 22e are openings for sucking the air and have a shape capable of preventing intrusion of foreign matters and the like. The number and the shape of the intake ports 22e can be set as appropriate. The intake ports 22e are provided at the end portions on the front surface side of both the side surfaces of the second housing 22 to be disposed below the exhaust ports 22f if the second housing 22 covers the first housing 21.

As illustrated in FIGS. 4 and 6, a plurality of exhaust ports 22f are provided in an opening shape capable of preventing intrusion of foreign matters and the like. For example, a total opening area of the exhaust ports 22f is set to be equal to or larger than a total opening area of the intake ports 22e.

Such a second housing 22 is configured by, for example, fixing a plurality of decorative panels configuring an outer wall to a frame. For example, at least a part of the decorative panels is detachably fixed to the frame. The cover 22c configures a part of the decorative panel on a surface of the second housing 22 opposed to the first housing 21.

As illustrated in FIGS. 8 to 11, the hinge section 23 rotatably supports the second housing 22 with respect to the first housing 21. The hinge section 23 brakes rotation of the second housing 22 and urges the second housing 22 from the closed position toward the open position.

As a specific example, the hinge section 23 includes a pair of rotating shafts 25, dampers 26 provided in the pair of rotating shafts 25, and urging members 27 provided in the rotating shafts 25.

The rotating shafts 25 rotatably support the first housing 21 and the second housing 22. For example, the rotating shafts 25 are fixed to one of the first housing 21 and the second housing 22 and held by the other of the first housing 21 and the second housing 22 via the dampers 26 to rotatably support the second housing 22 with respect to the first housing 21. The rotating shafts 25 are configured by, for example, screws.

The pair of rotating shafts 25 is coaxially disposed at a predetermined interval. The predetermined interval is an interval for enabling the cable 20 to be disposed between the pair of rotating shafts 25 as illustrated in FIG. 9.

The dampers 26 are respectively provided in the pair of rotating shafts 25. The dampers 26 brake rotation of the second housing 22 around the rotating shafts 25 set as rotation centers. For example, a so-called oscillation damper is used as the dampers 26.

For example, the urging members 27 urge the second housing 22 from the closed position toward the open position. For example, the urging members 27 are torsion springs that urge the second housing 22 along a rotating direction around an axis. In the following explanation, the urging members 27 are assumed to be torsion springs 27.

The torsion springs 27 urge the second housing 22 in a direction in which the second housing 22 rotates from the closed position toward the open position. An urging force of the torsion springs 27 is set the strongest if the second housing 22 is in the closed position. The torsion springs 27 are set to be capable of applying an urging force slightly larger than the weight of the second housing 22 to the second housing 22.

For example, a neutral point of the torsion springs 27 where an urging force is not generated is set in the open position of the second housing 22 or a position slightly further shifting in a direction away from the closed position than the open position. That is, the torsion springs 27 do not urge the second housing 22 if the second housing 22 is in the open position or urges the second housing 22 in the direction away from the closed position if the second housing 22 is in the open position. As the second housing 22 rotates from the open position toward the closed position, the torsion springs 27 gradually increase an urging force for urging the second housing 22 in a direction against the rotating direction of the second housing 22.

Such torsion springs 27 are provided in one or both of the pair of rotating shafts 25. If the torsion springs 27 are provided in the pair of rotating shafts 25, a pair of torsion springs 27 is set to generate a desired urging force. If the torsion spring 27 is provided in one rotating shaft 25, one torsion spring 27 is set to generate the desired urging force. In this embodiment, the torsion springs 27 are respectively provided in the pair of rotating shafts 25.

One ends of the torsion springs 27 are supported by the first housing 21. The other ends of the torsion springs 27 are supported by the second housing 22. As a specific example, the torsion springs 27 are supported by first seat sections 27a provided in the first housing 21 and second seat sections 27b provided in the second housing 22. The first seat sections 27a and the second seat sections 27b supports the end portions of the torsion springs 27 in one direction around the rotating shafts 25. The first seat sections 27a and the second seat sections 27b are provided in the first housing 21 and the second housing 22 to enable the end portions of the torsion springs 27 to be disposed from the axial direction of the rotating shafts 25.

As illustrated in FIGS. 1 to 3 and FIG. 6, the printer 11 includes the sheet storing section 31, a head 32, a platen 33, a driving mechanism 34, and a paper discharge port 35. The printer 11 supplies roll paper to the head 32 with the platen 33 and prints the roll paper with the head 32. For example, the roll paper is configured by winding belt-like heat-sensitive paper long in one direction that develops a color through heating.

As illustrated in FIGS. 1 to 3 and FIG. 6, the sheet storing section 31 is provided in an upper part of the first housing 21. The sheet storing section 31 is configured by recessing the upper part of the first housing 21 in a semi-columnar shape to be capable of storing the roll paper in a direction in which the axis of the roll paper is orthogonal to the front-rear direction of the housing 10 and the gravity direction. Consequently, the roll paper is fed in a direction from the rear surface side, which is the hinge section 23 side, to the front surface side, which is the side opposed to the hinge section 23, of the housing 10.

The head 32 is a thermal head. As illustrated in FIGS. 2 and 7, the head 32 is configured to be capable of partially generating heat in a width direction orthogonal to the feeding direction of the roll paper during the paper supply, that is, the direction from the rear surface side toward the front surface side of the housing 10. The head 32 is disposed in an upper part of the first housing 21 and further on the front surface side than the sheet storing section 31.

The platen 33 is a so-called platen roller. As illustrated in FIGS. 2 and 8, the platen 33 is provided in a position of the second housing 22 opposed to the head 32 provided in the first housing 21. The platen 33 sandwiches heat-sensitive paper between the platen 33 and the head 32. The platen 33 is driven to rotate by the driving mechanism 34 to convey the heat-sensitive paper along the feeding direction.

The driving mechanism 34 is configured by, for example, a motor and a gear and rotates the platen 33 around one axis.

As illustrated in FIGS. 1 and 2, the paper discharge port 35 is an opening provided on the front surface of the housing 10 and in a part where the first housing 21 and the second housing 22 are opposed to each other. The roll paper is discharged from the opening. The paper discharge port 35 includes, for example, a cutter provided in the first housing 21. The cutter cuts the roll paper.

As illustrated in FIG. 3, the first substrate 17 includes controllers electrically connected to the head 32 and the driving mechanism 34 and configured to control the operations of the head 32 and the driving mechanism 34. The first substrate 17 is electrically connected to the second substrate 18 by the cable 20.

The display section 12 includes, for example, a liquid crystal display and glass that protects the surface of the liquid crystal display. As illustrated in FIGS. 1 and 6, the display section 12 is disposed over substantially the entire outer surface of the second housing 22 configuring the upper surface of the housing 10. The display section 12 is configured to be capable of displaying information. The display section 12 is ON in a state in which the display section 12 displays the information. The display section 12 is OFF in a state in which the display section 12 hides the information.

The operation section 13 is an input section for inputting a key signal for operating the processing terminal 1. The operation section 13 is, for example, a touch panel. As illustrated in FIGS. 1 and 6, for example, the operation section 13 is disposed between the liquid crystal display and the glass of the display section 12 or provided integrally with the glass. The operation section 13 is disposed in the same range as the display section 12 or disposed in a range wider than the display section 12. The operation section 13 recognizes touch operation and transmits an input signal by the touch operation to the second substrate 18. The operation section 13 may include hard keys such as buttons besides the touch panel. The operation section 13 is ON in a state in which the operation section 13 transmits the input signal to the second substrate 18 and a function of the operation section 13 is enabled. The operation section 13 is OFF in a state in which the operation section 13 does not generate the input signal by the operation of the operation section 13 or stops the transmission of the input signal to the second substrate 18 and the function of the operation section 13 is stopped.

As illustrated in FIG. 1, the card reader writer 14 is provided on one side surface of the second housing 22. The card reader writer 14 is configured to be capable of reading information recorded in a card and writing information in the card. The card is a settlement card such as a credit card or a prepaid card.

As illustrated in FIGS. 3 and 4, the I/O port 15 is a connector such as a USB provided on an I/O board. The I/O port 15 is connected to a terminal 100 of a cable connected to a peripheral device 200 or the like.

The opening and closing sensor 16 detects a closed state and an open state of the processing terminal 1. For example, as illustrated in FIGS. 6 and 7, the opening and closing sensor 16 is disposed near the head 32 of the first housing 21. If the platen 33 comes into contact with the head 32, the opening and closing sensor 16 is operated by a member provided in the platen 33 or around the platen 33 and configured to operate the opening and closing sensor 16. The opening and closing sensor 16 transmits information concerning the operation to the first substrate 17 and the second substrate 18 as a signal.

The closed state of the processing terminal 1 means a state in which the position of the second housing 22 with respect to the first housing 21 is present in a closed position and the second housing 22 is fixed to the first housing 21 by the lock mechanism 19. The open state of the processing terminal 1 means a state in which the fixing of the second housing 22 to the first housing 21 by the lock mechanism 19 is released and the second housing 22 is present in any position between a position where the second housing 22 is slightly apart from the first housing 21 and an open position. In other words, the open state of the processing terminal 1 means a state in which the user can rotate the second housing 22 toward the closed position.

As a specific example, if the processing terminal 1 is in the closed state, the opening and closing sensor 16 is turned on and transmits signals to the first substrate 17 and the second substrate 18.

If the processing terminal 1 is in the open state, the opening and closing sensor 16 is turned off and stops the transmission of the signals to the first substrate 17 and the second substrate 18. The second housing 22 is urged toward the open position by the torsion springs 27. Therefore, if the fixing of the second housing 22 to the first housing 21 by the lock mechanism 19 is released, the second housing 22 slightly moves from the closed position toward the open position with the urging force of the torsion springs 27. Consequently, the processing terminal 1 changes to the open state. The head 32 and the platen 33 are separated. Accordingly, if the fixing of the second housing 22 to the first housing 21 by the lock mechanism 19 is released, the processing terminal 1 changes to the open state and the opening and closing sensor 16 is turned off even if the user does not rotate the second housing 22.

The first substrate 17 is connected to the second substrate 18 via the cable 20. The first substrate 17 is fixed in the first housing 21. For example, the first substrate 17 is connected to the I/O port 15. A circuit element is mounted on the first substrate 17.

As illustrated in FIGS. 2 and 7, the second substrate 18 includes a substrate 41 and a circuit element 42 mounted on the substrate 41. The substrate 41 is housed in the second housing 22. At least a part of the substrate 41 configures the mounting section 22d. At least the part of the substrate 41 configuring the mounting section 22d of the substrate 41 is disposed in a position opposed to the opening 22a. The circuit element 42 includes, for example, a processor 51, a ROM 52, a RAM 53, and an SSD 54. Apart of the circuit element 42 is, for example, configured to be detachably attachable to the substrate 41. The second substrate 18 is housed in the second housing 22 and disposed in a position where the part of the circuit element 42 detachably attachable to the substrate 41 is opposed to the opening 22a.

As illustrated in FIG. 3, the processor 51 is connected to the ROM 52, the RAM 53, the SSD 54, the display section 12, the operation section 13, the I/O port 15, the opening and closing sensor 16, and the controllers included in the first substrate 17 via a system transmission path 55. The system transmission path 55 includes an address bus, a data bus, and a control signal line. The processor 51 is a control section that controls, based on an operating system, middleware, and application programs stored in the ROM 52 and the RAM 53, the sections in order to realize various functions of the processing terminal 1.

As illustrated in FIGS. 2, 7, and 8, the lock mechanism 19 includes an engaging section 61 provided in the first housing 21, a section to be engaged 62 provided in the second housing 22, and an operation body 63 provided on the outer surface of the first housing 21 and configured to operate the engaging section 61.

If the second housing 22 moves to the closed position, the engaging section 61 and the section to be engaged 62 engage and the lock mechanism 19 fixes the second housing 22 to the first housing 21. If the operation body 63 is operated, the lock mechanism 19 disengages the engaging section 61 and the section to be engaged 62 to enable the second housing 22 to rotate from the closed position toward the open position. The operation body 63 is, for example, a button mechanically connected to the engaging section 61. If the button is pressed, the button operates the engaging section 61 to change from a state in which the engaging section 61 engages with the section to be engaged 62 to a state in which the engaging section 61 is disengaged from the section to be engaged 62.

The cable 20 electrically connects the first substrate 17 and the second substrate 18. As illustrated in FIGS. 9 and 11, the cable 20 is disposed in the first housing 21 to the second housing 22 via a space provided between the pair of rotating shafts 25 of the hinge section 23. FIG. 11 illustrates a state in which one side of the cable 20 is detached. Such a cable 20 is, for example, a so-called flat cable or a flexible circuit board.

The cable 20 is formed in, for example, a sheet shape, the length of which in a width direction orthogonal to a direction in which the first substrate 17 and the second substrate 18 are connected, that is, the longitudinal direction of the cable 20 is shorter than the distance between the pair of rotating shafts 25. The length in the longitudinal direction of the cable 20 is set to length enough for connecting the first substrate 17 and the second substrate 18 irrespective of where the second housing 22 is present between the closed position and the open position. The cable 20 includes, at both end portions, connectors 20a connected to the first substrate 17 and the second substrate 18. The cable 20 is not limited to the flat cable. Other cables 20 may be used if the cables 20 can connect the first substrate 17 and the second substrate 18 and can be disposed between the pair of rotating shafts 25.

As an example of use of the processing terminal 1 configured in this way, operation for opening and closing the second housing 22 with respect to the first housing 21 is explained.

First, as illustrated in FIG. 1, in the closed state in which the settlement processing and the like of the processing terminal 1 are performed, the second housing 22 is fixed to the first housing 21 by the lock mechanism 19. At this time, if the opening and closing sensor 16 detects the closed state of the processing terminal 1 and the processor 51 receives a signal transmitted by the opening and closing sensor 16, the processor 51 realizes various functions of the processing terminal 1.

For example, in use of the processing terminal 1, if supply of the roll paper is necessary, the operation body 63 of the lock mechanism 19 is operated for the supply of the roll paper. The engaging section 61 and the section to be engaged 62 are disengaged by the operation.

If the engaging section 61 and the section to be engaged 62 are disengaged, the second housing 22 separates from the first housing 21 with the urging force of the torsion springs 27. Consequently, the processing terminal 1 changes to the open state. The second housing 22 is capable of rotating with respect to the first housing 21. At this time, the opening and closing sensor 16 detects the open state of the processing terminal 1 and stops the transmission of the signal. Therefore, the processor 51 stops the various functions of the processing terminal 1.

Subsequently, if the second housing 22 is rotated by the user and reaches the open position as illustrated in FIG. 2, the sheet storing section 31 is exposed on the upper surface of the first housing 21. Consequently, the roll paper can be supplied. If the second housing 22 is rotated to the open position, the rotation of the second housing 22 is braked by the dampers 26. However, the torsion springs 27 urge the second housing 22 in a direction from the closed position side toward the open position. Therefore, the torsion springs 27 support the rotating operation by the user. A force required for the rotating operation can be reduced.

After the supply of the roll paper ends, if the second housing 22 is rotated from the open position to the closed position by the user and reaches the closed position, the second housing 22 comes into contact with the upper surface of the first housing 21. The second housing 22 is fixed to the first housing 21 by the lock mechanism 19. Consequently, as illustrated in FIG. 1, the processing terminal 1 changes to the closed state.

If the second housing 22 rotates from the open position to the closed position and an inclination angle of the second housing 22 with respect to the gravity direction increases, torque increases with the own weight of the second housing 22. A force of the user necessary for supporting the own weight of the second housing 22 during the rotation of the second housing 22 also increases. However, the rotation of the second housing 22 is braked by the dampers 26. The second housing 22 is urged by the torsion springs 27 in the opposite direction of the rotating direction from the open position to the closed position. That is, rotating speed of the second housing 22 is reduced by the dampers 26. A force is generated in a direction against the rotating direction of the second housing 22 by the torsion springs 27.

Therefore, if the second housing 22 is rotated from the open position to the closed position, a force necessary for the user to support the second housing 22 can be reduced. In addition, the urging force of the torsion springs 27 is set the largest in the closed position. Therefore, even if torque generated in the second housing 22 increases as the inclination angle of the second housing 22 increases, it is possible to prevent the force of the user for supporting the second housing 22 from increasing. Depending on setting of the torsion springs 27, it is also possible to substantially fix a force required for supporting the second housing 22 if the second housing 22 rotates from the open position to the closed position.

With the processing terminal 1 configured as explained above, if the second housing 22 is rotated from the closed position side to the open position, it is possible to support the rotation of the second housing 22 with the urging force of the torsion springs 27. If the second housing 22 is rotated from the open position to the closed position, the processing terminal 1 generates a force resisting the rotation of the second housing 22 with the urging force of the torsion springs 27 and brakes the rotation of the second housing 22 with the dampers 26. Consequently, it is possible to prevent the rotating speed from increasing if the second housing 22 is moved from the open position to the closed position and reduce the force of the user for supporting the second housing 22.

Consequently, the processing terminal 1 can improve operability of opening and closing operation. In particular, if the display section 12, the second substrate 18, and the like are provided in the second housing 22, the weight of the second housing 22 increases. However, it is possible to reduce the operability of the opening and closing operation even if the weight of the second housing 22 increases. Since the weight of the second housing 22 can be increased, various components can also be disposed in the second housing 22. It is also possible to improve a degree of freedom of design.

By providing the dampers 26 and the torsion springs 27, it is possible to reduce torque required by the dampers 26 in order to brake the second housing 22. Therefore, it is possible to prevent operability in rotating the second housing 22 toward the open position.

In the processing terminal 1, by disposing the pair of rotating shafts 25 and the dampers 26 at an interval for enabling the cable 20 to be disposed, it is possible to secure a disposition space for the cable 20 or the like that connects the first substrate 17 and the second substrate 18. That is, it is unnecessary to separately secure a space for disposing the cable 20 or the like. It is possible to reduce the size of the processing terminal 1.

Further, if the second housing 22 is moved from the open position to the closed position, even if the user releases holding of the second housing 22 by mistake, it is possible to reduce, with the dampers 26 and the torsion springs 27, the rotating speed by the own weight of the second housing 22. Consequently, it is possible to prevent the second housing 22 from powerfully colliding with the first housing 21. Therefore, it is possible to prevent the second housing 22 from being broken and prevent fingers from being caught by the first housing 21 and the second housing 22. Therefore, it is also possible to improve safety of a product and safety during use.

As explained above, with the processing terminal 1 according to this embodiment, by providing the dampers 26 and the torsion springs 27 in the hinge section 23 that rotatably supports the second housing 22 with respect to the first housing 21, it is possible to improve operability in rotating the second housing 22 with respect to the first housing 21.

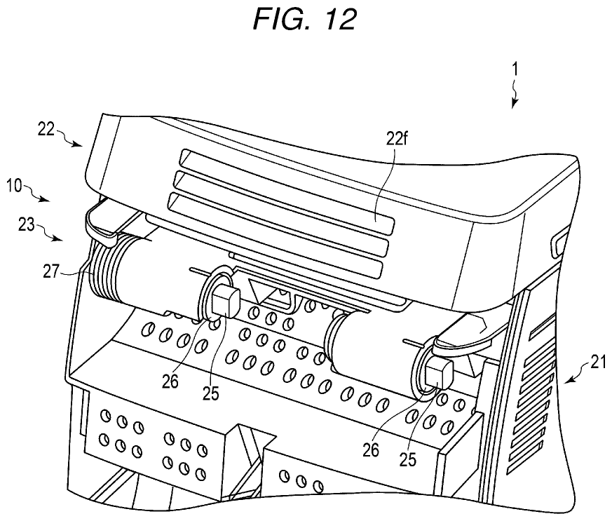

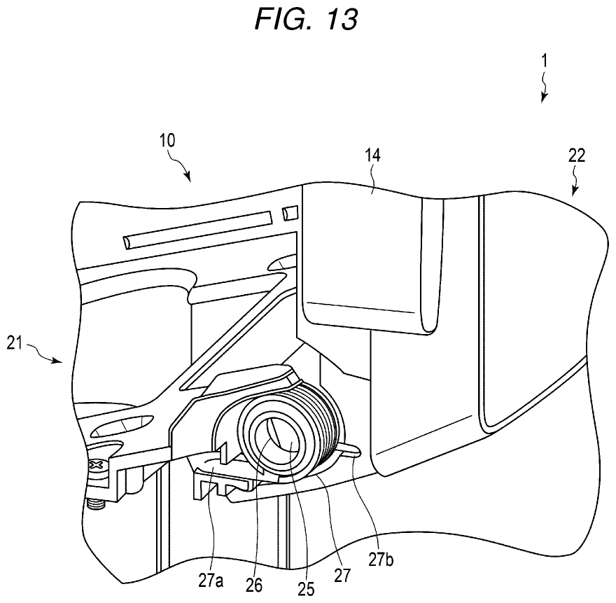

This embodiment is not limited to the example explained above. For example, in the example explained above, the configuration is explained in which the rotating shafts 25 configured by the screws or the like are used in the processing terminal 1. However, this embodiment is not limited to this configuration. For example, as illustrated in FIG. 12, assembled components obtained by integrally assembling the rotating shafts 25 and the dampers 26 may be used. The configuration is explained in which the pair of torsion springs 27 is used. However, this embodiment is not limited to this configuration. As illustrated in FIGS. 12 and 13, a configuration may be adopted in which one torsion spring 27 is provided in the rotating shaft 25 and the damper 26 on one side. If only one torsion spring 27 is provided, a necessary urging force is set larger than the urging force of the pair of torsion springs 27. The diameter of the torsion spring 27 and a wire diameter also increase. A rate of change of the diameter of the torsion spring 27 during deformation also increases. Therefore, it is desirable to increase a space of a setting space for the torsion spring 27.

With the processing terminal 1 in at least one embodiment explained above, it is possible to improve operability in rotating the second housing 22 with respect to the first housing 21.

The several embodiments are explained above. However, the embodiments are presented as examples and are not intended to limit the scope of the invention. These new embodiments can be implemented in other various forms. Various omissions, substitutions, and changes can be made without departing from the spirit of the invention. These embodiments and modifications of the embodiments are included in the scope and the gist of the invention and included in the inventions described in claims and the scope of equivalents of the inventions.

What is claimed is:

1. A processing terminal, comprising:
a first housing;
a second housing;
a rotating shaft configured to rotatably support the second housing with respect to the first housing;
a damper provided in the rotating shaft and configured to brake rotation of the second housing between an open position where the second housing is separated from the first housing and a closed position where the second housing covers the first housing; and
an urging member provided in the rotating shaft and configured to urge the second housing from the closed position toward the open position at least in the closed position.

2. The terminal according to claim 1, wherein the urging member is a torsion spring, an urging force of which gradually increases as the second housing rotates from the open position toward the closed position.

3. The terminal according to claim 2, wherein
the first housing includes a first substrate,
the second housing includes a second substrate and a display section connected to the first substrate via a cable,
a pair of the rotating shafts is provided at an interval for positioning the cable between the pair of rotating shafts,
the damper is provided in each of the pair of rotating shafts, and
opposite ends of the torsion spring are supported by the first housing and the second housing, respectively.

4. The terminal according to claim 1, further comprising a lock mechanism configured to fix and release the first housing and the second housing in the closed position.

5. The terminal according to claim 3, wherein
the first housing includes a storing section configured to store roll paper,
the second substrate is disposed in the second housing, and
the second housing includes an opening opposed to the first housing in the closed position and at least opposed to a part of the second substrate where a replacement member is mounted.

6. The terminal according to claim 1, wherein
the urging member is further configured to gradually increase an urging force for urging the second housing in a direction against the rotating direction of the second housing as the second housing rotates from the open position toward the closed position.

7. The terminal according to claim 1, further comprising:
a second urging member provided in the rotating shaft and configured to urge the second housing from the closed position toward the open position at least in the closed position.

8. The terminal according to claim 1, further comprising:
a printer.

9. The terminal according to claim 1, further comprising:
a credit card reader.

10. The terminal according to claim 3, wherein
the cable has a sheet shape.

11. A POS terminal, comprising:
a first housing;
a second housing;
a rotating shaft configured to rotatably support the second housing with respect to the first housing;
a damper provided in the rotating shaft and configured to brake rotation of the second housing between an open position where the second housing is separated from the first housing and a closed position where the second housing covers the first housing; and
an urging member provided in the rotating shaft and configured to urge the second housing from the closed position toward the open position at least in the closed position.

12. The POS terminal according to claim 11, wherein the urging member is a torsion spring, an urging force of which gradually increases as the second housing rotates from the open position toward the closed position.

13. The POS terminal according to claim 12, wherein
the first housing includes a first substrate,
the second housing includes a second substrate and a display section connected to the first substrate via a cable,
a pair of the rotating shafts is provided at an interval for positioning the cable between the pair of rotating shafts,
the damper is provided in each of the pair of rotating shafts, and
opposite ends of the torsion spring are supported by the first housing and the second housing, respectively.

14. The POS terminal according to claim 11, further comprising a lock mechanism configured to fix and release the first housing and the second housing in the closed position.

15. The POS terminal according to claim 13, wherein
the first housing includes a storing section configured to store roll paper,
the second substrate is disposed in the second housing, and
the second housing includes an opening opposed to the first housing in the closed position and at least opposed to a part of the second substrate where a replacement member is mounted.

16. The POS terminal according to claim 11, wherein
the urging member is further configured to gradually increase an urging force for urging the second housing in a direction against the rotating direction of the second housing as the second housing rotates from the open position toward the closed position.

17. The POS terminal according to claim 11, further comprising:
a second urging member provided in the rotating shaft and configured to urge the second housing from the closed position toward the open position at least in the closed position.

18. The POS terminal according to claim 11, further comprising:
a printer.

19. The POS terminal according to claim 11, further comprising:
a credit card reader.

20. The POS terminal according to claim 13, wherein
the cable has a sheet shape.
